(19) United States
(12) Patent Application Publication
(10) Pub. No.: US 2002/0033704 A1
(43) Pub. Date: Mar. 21, 2002

(54) Cotton moisture meter

(76) Inventors: Steve Moffett, Lubbock, TX (US); Paul Mohr, Alamogordo, NM (US); John W. Ballinger, Lubbock, TX (US)

Correspondence Address: CONLEY ROSE & TAYON, P.C., P. O. BOX 3267, HOUSTON, TX, 77253-3267, US

(21) Appl. No.: 09/871,203

(22) Filed: May 31, 2001

Related U.S. Application Data
(63) Continuation-in-part of application No. 09/332,353, filed on Jun. 11, 1999, now Pat. No. 6,275,046.
(60) Provisional application No. 60/128,013, filed on Apr. 6, 1999.

(51) Int. Cl. G01R 27/04; G01R 27/32

(52) U.S. Cl. 324/640

(57) ABSTRACT

The method and structure of a moisture measuring device that creates an electric field, but substantially no related electromagnetic wave, and then determines a moisture content of a specimen based on the effect the moisture of the specimen has on the electric field.

### CROSS REFERENCE TO RELATED APPLICATION

Applicants filed a Provisional Application on this subject matter on Apr. 6, 1999, Serial No. 60/128,013. Specific reference is made to that document, and it is incorporated by reference herein as if reproduced in full below.

Further, this application is a Continuation-In-Part of application Ser. No. 09/332,353 filed Jun. 11, 1999, now U.S. Pat. No. ______ This application claims priority from the Ser. No. 09/332,353 application, and that application is incorporated by reference herein as if reproduced in full below.

### BACKGROUND OF THE INVENTION

1. Field of the Invention

This invention relates to the non-invasive measurement of moisture content of various materials. Electronic technicians have ordinary skill in this art.

2. Description of the Related Art

The related art is replete with devices for the non-invasive measurement of moisture content by use of electromagnetic waves. Although each application varies in its exact method of operation, for the most part each of the related art devices has a radio or microwave frequency signal generator which feeds an antenna. This antenna acts to transmit an electromagnetic wave through the specimen whose moisture content is to be measured. Opposite to, or otherwise in receiving relationship to, the transmission antenna is a receiving antenna. Between the two antennas in operational relationship is a specimen space wherein the specimen to be measured is placed during the measurement procedure.

The principle of operation of the related art devices is simply that an electromagnetic wave propagates through the specimen in question. The receiving antenna receives the electromagnetic wave and calculates an amount or percentage of water in the specimen based on any of a number of characteristics of the electromagnetic wave including signal strength, polarization, attenuation or absorption of the electromagnetic wave, phase angle or scattering of the electromagnetic wave.

The antennae of the related art devices are usually horn type directional wave guides, placed as close as possible to the specimen, that direct the propagating electromagnetic wave through a small or at least a particular portion of the specimen measured. If the transmitting horn cannot direct the propagating wave across the entire specimen at one time, an accurate reading of the moisture content in the overall specimen requires an average across the specimen.

The typical frequencies of electromagnetic waves used in the related art devices are in the microwave or radio frequency ranges. Using these high frequency electromagnetic waves creates a host of problems like: complex electric circuitry to create the high frequency signal; high frequency current amplification systems; impedance matching systems; matched polarization transmission and receiving antennae; superheterodyne receiving circuitry; and all the shielding necessary in such high frequency circuits to prevent unwanted noise and cross talk.

The related art devices measure the moisture content of specimens such as gypsum board, baled material including cotton, cotton and other materials as they fall within a chute, and other fibrous substances. The term cotton includes lint cotton, that is cotton already ginned or removed from the seed, and seed cotton, which has the cotton fibers still attached to the cotton seed.

### SUMMARY OF THE INVENTION

Progressive Contribution to the Art

This invention measures the moisture of a specimen by generating an electric field with an electric field creation unit and then detecting that specimen's effect on the electric field with an electric field detection unit. By creating and detecting the presence or strength of an electric field, rather than having to transmit and receive an electromagnetic wave, the hardware required is not as complicated as that for the electromagnetic wave devices. Additionally, the frequencies at which the device operates can be significantly lower than the related art devices.

Objects of this Invention

An object of this invention is to measure moisture content of a specimen.

An object of this invention is to measure the moisture content of a specimen by creation and detection of an electric field through the specimen.

An object of this invention is to detect the moisture content of a specimen by measuring a field intensity increase based on the specimen's concentration of an electric field because of its moisture content.

An object of this invention is to measure the moisture content of a specimen by detecting an absence of an electric field because the moisture of a specimen placed therein directs the electric field to a ground plate.

An object of this invention is to detect the moisture content of a specimen as the specimen falls from an upper level to a lower level past a field generation plate and field detection plate.

An object of this invention is to measure the moisture content of baled cotton by detecting an increase or decrease in the electric field associated with the presence of moisture within baled cotton.

An object of this invention is to detect the moisture content of loose cotton as it falls past a detection device by detecting the attenuation or concentration of the electric field as a function of the moisture content therein.

Further objects are to achieve the above with devices that are sturdy, compact, durable, lightweight, simple, safe, efficient, versatile, ecologically compatible, energy conserving, and reliable, yet inexpensive and easy to manufacture, install, operate, and maintain.

Other objects are to achieve the above with a method that is rapid, versatile, ecologically compatible, energy conserving, efficient, and inexpensive, and does not require highly skilled people to install, operate, and maintain.

The specific nature of the invention, as well as other objects, uses, and advantages thereof, will clearly appear from the following description and from the accompanying drawings, the different views of which are not necessarily scale drawings.

### BRIEF DESCRIPTION OF THE DRAWINGS

FIG. 1 is a block diagram representation of the invention.

FIG. 2 is a representation showing the relationship of a transmission plate, electric field lines, and a receiving plate with no specimen present and in the absence of a ground plate.

FIG. 3 shows the relationship of the transmission plate, the electric field lines, and the receiving plate when a ground plate is present.

FIG. 4 shows the relationship of the transmission plate, the electric field lines, and the receiving plate when there is a specimen between the plates.

FIG. 5 shows the relationship of the transmission plate, the electric field lines, and the receiving plate when there is a specimen between the plates and there is present a ground plate.

FIG. 6 is a perspective partial cut-away view showing placement of the transmission plate and three receiving plates with a cotton bale as a specimen.

FIG. 7 shows a preferred design of a receiving plate.

FIG. 8 shows an embodiment of the invention used to detect the moisture content of falling cotton as in a chute.

FIG. 9 shows an embodiment of the invention to detect the moisture content of cotton as it falls across a sloped surface.

FIG. 10 shows a partial electrical schematic of the relationship of the receiving plates and the detection circuit.

### Catalogue of Elements

As an aid to correlating the terms of the claims to the exemplary drawing(s), the following table containing a catalog of elements is provided:

TABLE 1

| | | | |
|---|---|---|---|
| 6 | electric field generator | 30 | conductive material |
| 8 | electric field detector | 32 | cotton |
| 10 | signal generator | 50 | center pad |
| 12 | voltage amplifier | 52 | lead |
| 14 | transmission plate | 54 | lead |
| 16 | specimen | — | electric field lines |
| 18 | receiving plate | D | plate separation |
| 20 | detection circuit | H1 | transmission plate height |
| 22 | interface circuit | H2 | receiving plate height |
| 24 | ground plate | S1 | transmission plate to specimen spacing |
| 26 | cotton bale | S2 | receiving plate to specimen spacing |
| 28 | insulating material | | |

### DESCRIPTION OF THE PREFERRED EMBODIMENTS

The electric field creation unit in the preferred embodiment is an electric field generator 6. The electric field detection unit of the preferred embodiment is an electric field detector 8. The electric field generator 6 and the electric field detector 8 comprise the two main components of the preferred embodiment.

The electric field generator 6 comprises a signal generator 10, a voltage amplifier 12, and a transmission plate 14. Signal generator 10 of the device is used to generate electrical signals at the desired frequency. Voltage amplifier 12, as the name implies, takes the signal from the signal generator 10 and amplifies the voltage to appropriate levels. Finally, the transmission plate 14, an electrically conductive element, is coupled to the voltage amplifier 12. The electric field is created around the transmission plate 14.

The electric field detector 8 comprises three elements. The first of the three elements is at least one receiving plate 18, an electrically conductive element. The receiving plate 18 is coupled to a detection circuit 20. This portion of the device detects the electric field created by the electric field generator 6 as modified by the presence and water content of a specimen 16. Finally, an interface circuit 22 couples to the detection circuit 20 and creates a standard output signal proportional to the water content of the specimen 16.

The preferred embodiments measure the moisture content of a specimen when the specimen is in a specimen space. Where the specimen is gathered or baled, as for instance a bale of cotton, the specimen space is roughly defined by the volume of the specimen. However, the invention works equally well for measuring the moisture content of a loose or ungathered specimen. An example of this loose or ungathered specimen might be cotton falling within a chute (FIG. 8) or cotton sliding down an inclined feed means (FIG. 9) to a gin stand in a cotton gin. The specimen space in this instance will be defined as a cross-sectional area of the flow of the loose or ungathered specimen cutting a swath of volume as it crosses between transmission plate 14 and the receiving plate 18. In either case, the volume created by the specimen between the two plates will be the specimen space.

The generator 6 and the detector 8 measure the moisture content of the specimen by measuring the effect the specimen has on an electric field created by the device. Referring to FIG. 2, there are two electrically conductive plates labeled 14 and 18. For the purposes of explaining how the electric field is changed by the presence or absence of a specimen, it will be assumed in FIG. 2 that the two plates 14 and 18 are a significant distance from earth ground or any grounded conductor. If a voltage is applied to the transmission plate 14, an electric field is created thereby. As indicated by the dashed lines in FIG. 2, an electric field exists around the transmission plate 14. The dashed lines represent the electric field lines or the path of the flow of electric flux. The receiving plate 18 is preferably not coupled directly to ground and therefore the electric field is not significantly affected by the presence of the plate 18.

When a specimen 16 is placed between the transmission plate 14 and receiving plate 18, this placement affects electric field intensity. Referring to FIG. 4 there is a specimen 16 between the respective plates. The presence of the specimen 16 in this configuration tends to focus the electric field emanating from the transmission plate 14 toward the receiving plate 18 as shown. In this configuration, the detection system looks for an increase of electric field as an indication of more moisture content of the specimen. As the moisture content of the specimen increases, the field focusing characteristic of the moisture laden specimen increases. The moisture content of the specimen is indicated by the voltage induced on the receiving plate 18, which is directly proportional to the moisture content of the specimen.

Referring to FIG. 3 there is a second plate configuration embodiment. In this embodiment, in addition to the transmission and receiving plates 14 and 18 respectively, there is an additional ground plate 24, which is grounded, placed physically below plates 14 and 18. As seen in FIG. 3, the electric field is affected by the presence of the ground plate 24. In this configuration, the electric field, again indicated by dashed lines, varies between the transmission plate 14 and the ground plate 24. Referring to FIG. 5 there is indicated a specimen 16, being cotton bale 26, placed in the three plate configuration. The presence of the specimen 16 in this configuration tends to focus the electric field toward the ground plate 24. The detection circuitry, in combination with the receiving plate 18, determines a moisture content of the specimen based on how much of the electric field is diverted to the ground plate by the moisture of the specimen. In this configuration the voltage induced on the receiving plate 18 will be inversely proportional to the moisture content of the specimen.

The above description of the characteristics of the electric field is somewhat idealized. Indeed, in FIG. 2 the electric field lines would propagate outward in all directions equally, but are shown in the figure only to exist between the two plates in the specimen space to simplify the drawing. Likewise, FIGS. 4 and 5 showing the presence of a specimen directing the electric field lines either to the receiving plate 18, as seen in FIG. 4, or to the ground plate 24, as seen in FIG. 5, are drawn assuming a perfect transmission of electric flux through the specimen 16 and ignore the electric field effect beyond the plates.

When the specimen 16 is cotton the electric field focusing characteristic of the moisture laden cotton does not result in a significant electric field change when the moisture content of the cotton exceeds 20 percent. Along these same lines, if a bale of cotton 26 completely devoid of moisture content is placed between the transmission plate 14 and the receiving plate 18 of the configuration of FIG. 2, the electric field would be only slightly affected if at all by the presence of the cotton and therefore the electric field created by the transmission plate 14 would be substantially as indicated in FIG. 2. As the moisture content of the cotton 16 increases, the electric field strength at the receiving plate 18 increases proportionately. When the moisture content of the cotton bale 26 exceeds 20 percent, this represents a maximum field focusing effect and would create the situation as depicted in FIG. 4. Cotton is an example only of a possible specimen for use with this moisture measuring invention and is not intended to restrict the scope of the invention.

The description to this point has assumed a zero frequency voltage applied to the transmission plate 14. A unit working at zero frequency voltage may be operable in some locations where static electricity, and therefore static voltages and electric fields, are not a problem. However, if the invention is used in the presence of randomly fluctuating voltages created by static electricity, it would be desirable and advantageous for the voltage applied to the transmission plate 14 to be time varying at a particular frequency. The waveform of the voltage applied to the transmission plate 14 is contemplated to be substantially sinusoidal; however, the waveform of the applied voltage could be anything so long as the electric field detector 8 could discriminate the applied waveform from the random electric fields created by static electricity.

Although any frequency may be used for the time varying voltage applied to the transmission plate 14, the preferred embodiments use a frequency of 50 kHz. However, the invention should not be construed to be limited to the use of 50 kHz since any frequency could be used. The preferred 50 kHz was dictated by the frequency of noise generated in the particular application. The other noise generation devices included cathode ray tubes, switching power supplies, and specialty banding equipment used in many gins. It will be understood the descriptions of operation of the device using FIGS. 2- 5 will not change except that the electric field detected will be that field varying at 50 kHz, or whatever frequency is chosen based on the particular application, and other time varying electric fields induced on a receiving plate 18 are filtered out. Indeed, it would be possible that instead of using a particular frequency of electric field that the frequency of the electric field itself could change at a particular frequency. However, the electric circuitry required to implement such a complex frequency shifting operation would be substantially more than for a single frequency, but could still be an option for use in locations where significant ambient electric fields are present.

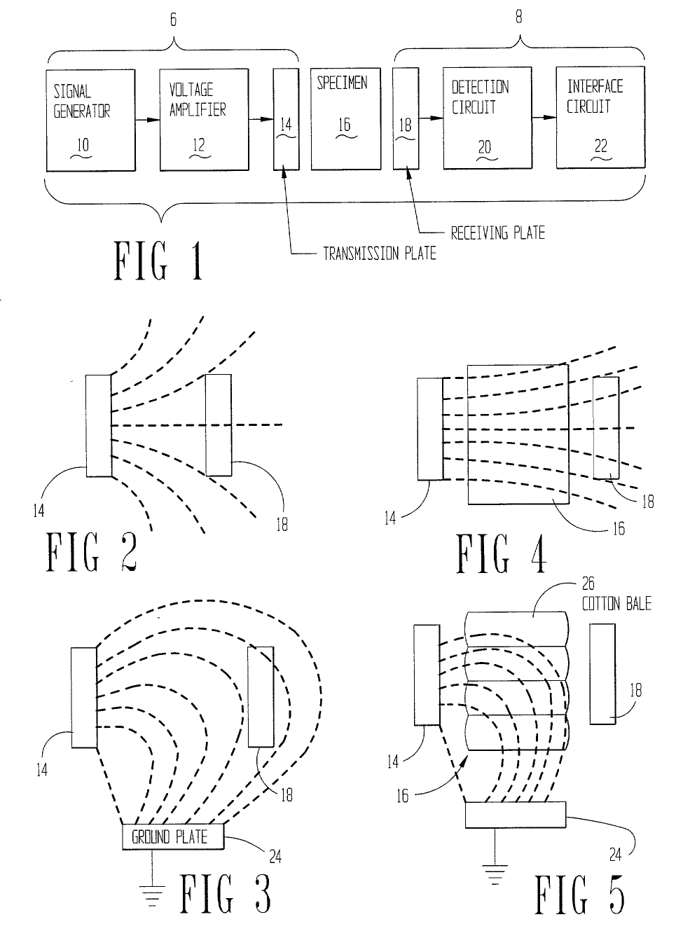

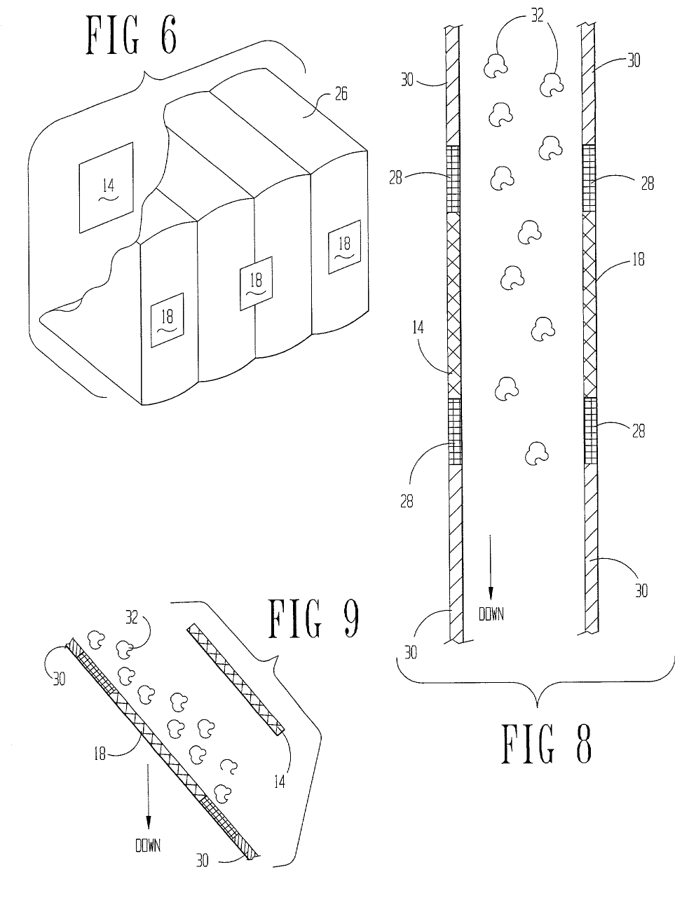

Although it is possible to build a moisture measuring device using only a single receiving plate 18 as indicated in FIGS. 1-5, the preferred embodiments of the present invention preferably use three receiving plates as shown in FIG. 6. The theory of operation of the device, however, does not change. Instead, voltage is induced on each of the receiving plates 18 proportional to the moisture of the specimen being measured. In the case of FIG. 6, the specimen is a cotton bale 26 shown in partial cut-away view so as not to hide the transmission plate 14. Preferably, the voltages induced on the three receiving plates 18 each indicate a moisture content, and these moisture contents are preferably summed and/or averaged to obtain the overall moisture reading. The electronics necessary to perform the voltage detection on each of the receiving plates 18 is described more thoroughly below.

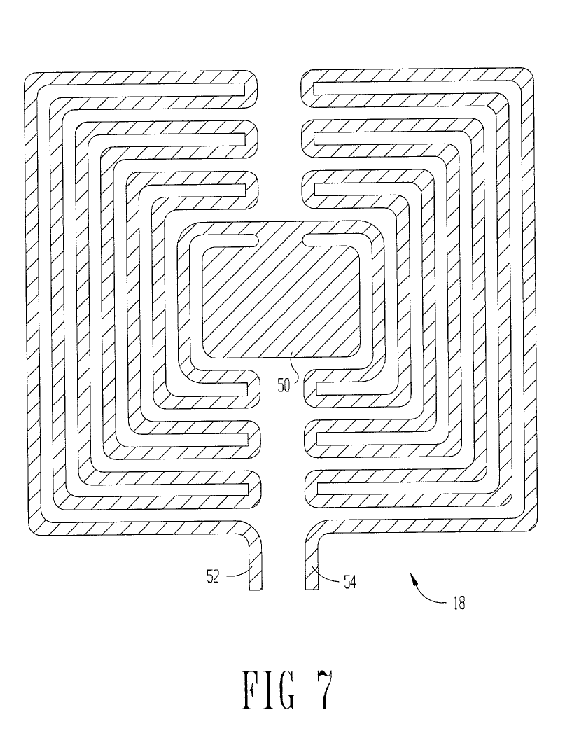

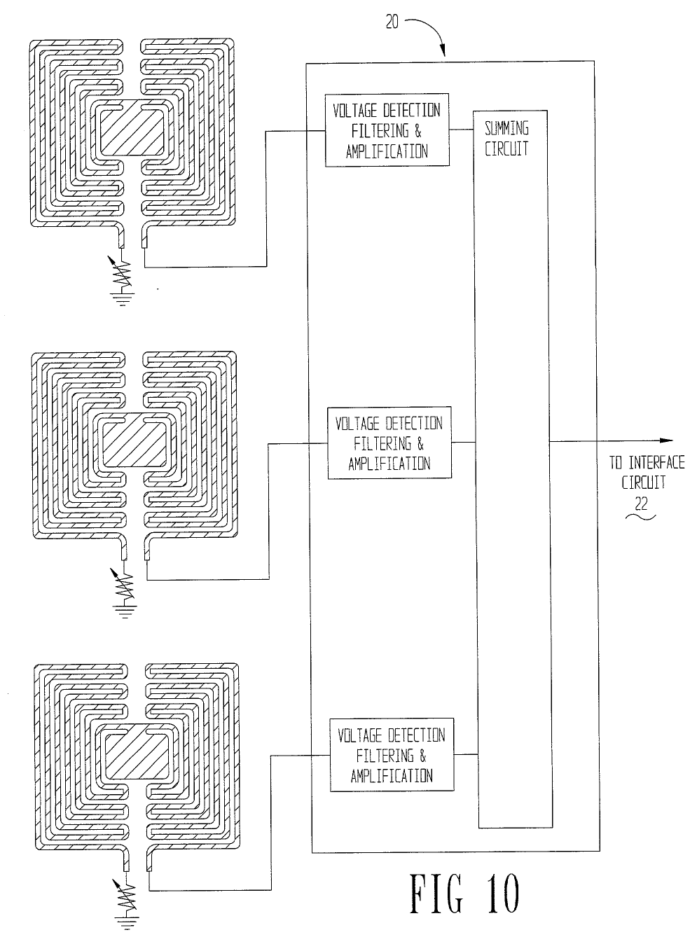

Referring now to FIG. 7, there is shown a preferred design of a receiving plate 18. The width and height of each of each receiving plate 18 is preferably 3 inches by 3 inches. Further, each receiving plate is preferably made of aluminum and has a thickness of 0.02 inches. As FIG. 7 indicates, the aluminum, or other metal that is used, is preferably etched, milled or otherwise cut into substantially the pattern shown. That pattern includes a single interior or center pad 50 surrounded by two strips of material or leads 52 and 54 that surround the center pad 50. Preferably, each of these strips of material form a labyrinth pattern around each side of the pad 50, and having their distal ends located near the bottom center of the receiving plate 18. One of these receiving ends, e.g., lead 54, preferably couples to the receiving electronics. The other receiving end, e.g., lead 52, preferably couples to ground through a variable one mega-ohm resistor. Voltage induced on the receiving plate 18 based on the intensity of the electric field is preferably detected by the electronics (discussed more thoroughly below), and the small charge collected on the receiving plate as a whole preferably bleeds to ground through the lead coupled to ground.

There is little or no restriction on the placement separation between the transmission plate and the receiving plates. In fact, the inventors have found that the device is operational with the receiving plates 18 having a separation from the specimen as great as six feet. However, it will be understood that the voltages necessary on the transmission plate 14 increase as plate separations increase. For embodiments measuring the moisture content of baled cotton 26, it is preferred that the transmission plate 14 be a reasonable distance from the bale 26, preferably six to eight inches. This separation distance is set by the requirement that the bale be able to move along a conveyor-type system without interference by the transmission plate 14. Likewise, it is preferred that the receiving plates 18 be located a reasonable distance from the specimen, when measuring baled cotton preferably six to eight inches. These preferred separations give the cotton bale sufficient room to move on the conveyor given the possible conveyor placement, without the need of increasing the transmission plate 14 applied voltage excessively.

The following is a description of the electrical circuitry used in an embodiment of the device. The electrical circuitry described is only one method of generating and detecting the electric field and as such should not be construed as limiting the breadth of the invention. Based on the frequencies used and the availability of electronic circuit components at the time of this application, the electrical circuit represents the best mode known to the inventor.

As previously mentioned, the preferred frequency of the voltage applied to the transmission plate 14 in this embodiment is 50 kHz. This 50 kHz signal is created in the preferred embodiment using a 1 MHz clock signal divided sequentially by 2 and then by 10 by use of two integrated circuit components MC14018 to get the desired frequency. The output of the MC14018 configured to divide by 10 is then preferably coupled an operation amplifier TL082 configured to act as an amplifier. From this point, the 50 kHz voltage signal moves from the signal generator 10 to the voltage amplification 12 portion of the device. It should be noted that the distinction between the signal generation circuit 10 and voltage amplifier circuit 12 is selected for purposes of description. Various components and functions could be transferred between to two circuits without deviating from the spirit of the invention.

471 As the name implies, the voltage amplification 12 portion of the circuit preferably takes the 50 kHz signal generated by the signal generator 10, increases the voltage, and applies that voltage to the transmission plate 14. Amplification in the described embodiment takes place by applying the 50 kHz signal to the base of a transistor, preferably a 2N3055. As is the function of a transistor, current is allowed to flow from the collector to the emitter relative to the current applied at the base. In this configuration, the 50 kHz signal applied to the base creates a time varying current flow in the primary of a step up transformer, preferably a F-3116X manufactured by Magnetek. The time varying current flow in the primary of the transformer couples, by means of magnetic flux, to the secondary of the transformer. This coupling creates a voltage in the secondary of the transformer, which voltage is applied to the transmission plate 14.

Summarizing the electric field generator of the overall electrical circuitry, the 1 MHz clock signal is sequentially divided by 2 and then 10 to result with a 50 kHz clock signal. This 50 kHz clock signal is applied to a voltage amplifier 12 that increases the voltage variably between 0 and 7,000 volts, but preferably 400 volts. It is the time varying voltage applied to the transmission plate 14 that creates a corresponding time varying electric field.

Detection and interpretation of the electric field is preferably done within the electric field detector 8. The receiving plates 18, by being placed in the electric field generated around the transmission plate 14, have a voltage induced upon them proportional to the strength of the electric field. The voltage induced on the receiving plates 18 is preferably fed to the detection circuit 20. Because the preferred embodiment of the present invention comprises three receiving plates, the detection circuit 20 preferably comprises three parallel detectors whose outputs are effectively summed and/or averaged to produce an output signal proportional to the moisture content of the specimen. In particular, the receiving plate arrangement shown in FIG. 7 effectively has two leads 52 and 54. Preferably, one of those leads is tied to common or ground through a one mega-ohm resistance. The second lead is preferably coupled to an operational amplifier, preferably a TL082, which takes the small voltages induced on the plate and amplifies that signal. Also, the operational amplifier coupled to the lead of the receiver plate preferably acts as a high pass filter, filtering out any voltages induced on the receiver plate 18 below the frequency of interest, preferably 50 kHz. One of ordinary skill in the art is fully capable of designing a high pass filter using an operational amplifier to perform this task. The output signal of the operational amplifier then preferably couples to the base of a transistor, preferably a 2N2222, which acts as a voltage amplifier. After amplification, the received signal then preferably passes through a diode, preferably a 1N914, which feeds on its output a capacitor. Preferably each of the receiving plates 18 have a circuit as described to high pass filter the received signal and amplify that signal before applying the voltage to a capacitor. Because each of the three received signals pass through a diode before being applied to the capacitor, the received signals are effectively summed and/or averaged to find an overall moisture content of the specimen.

There are many voltages created by static electricity in the operation of a cotton gin, or any of life's activities. The receiving plates 18 in combination with the detection circuit electronics create a signal for every electric field in the region of the receiving plate 18. However, the great majority of the electric fields created by operation of a cotton gin will not be periodic. That is, the electric fields generated by static electricity may vary in time, but this variance is only transitory. They will not vary at a particular frequency. To differentiate between electric fields created by static electricity and the electric field generated by this invention, the detection circuit 20 preferably filters signals representing detected electric fields, except for those signals created by electric fields varying at 50 kHz. If the frequency of operation of the device is changed because of parameters of the particular application, the filtering changes to a cut-off frequency just below the frequency of operation. The remaining circuitry creates an output signal varying from 4 milli-amps to 20 milli-amps based on the summed voltages from the receiving plates, A 4 to 20 milli-amp signal is a standard interface signal that is compatible with many forms of control and monitoring equipment.

### Best Mode and Operational Limits

There are many parameters of operation of this moisture measuring device that may be adjusted without undue adverse impact upon operation of the device. This section is to solidify what the inventors consider the best mode of operation of this moisture measuring device at the time of the filing of this application.

As previously mentioned, using the device to measure the moisture content of cotton in a cotton gin, the frequency of the best mode is 50 kHz. However, any frequency may be operational in the correct circumstances. To the best of our knowledge, there is no theoretical upper frequency limit at which the device is no longer operable. At present, only technical and economic limitations related to availability and price of components to create and detect the electric fields limit the potential upper range frequencies. Additionally, in the right circumstances even a zero frequency voltage could be applicable.

The specification speaks of electrically conductive elements and electrically conductive plates. As of the filing date of this invention the best mode is the use of the transmission plate made of aluminum having a thickness of 0.02 inches, preferably having a width of 5 inches and a height of 8 inches. As mentioned above, the preferred embodiments also comprise three receiving plates preferably made from aluminum and having a preferred thickness of 0.02 inches. As shown in FIG. 7, it is preferred that each of the receiving plates be constructed to have a pattern substantially as that shown in FIG. 7. Further, it is preferred that the receiving plates each have widths and heights of 3 inches (effectively square). It is further preferred that the receiving plates 18 lie at substantially the same elevation, lie in the same plane (co-planer) and have a separation of 6 inches between them. It must be understood, however, that these sizes, dimensions and placements are not critical to operation of the device. Many modifications as to the exact construction and material of the receiving and transmission plates, their placement relative to each other, including their elevations on the specimen, and their locations with respect to the specimen could change without deviating from the spirit of this invention. For example, it is possible to make an operational device using substantially solid receiving plates 18. Likewise, an operational device may have only a single receiving plate.

For ease of construction and to make a more aesthetically pleasing product, in the preferred embodiment the electric field generator 6, which includes the signal generator 10, voltage amplifier 12, and transmission plate 14, are all housed in a plastic box. That is, if one approached the device in operation one could not electrically contact the transmission plate 14 or any of the electrical circuitry of the electric field generator 6 as it would all be contained in a sealed electrical box. Likewise, the electric field detector 8 which includes the receiving plates 18, detector circuit 20, and interface circuit 22 are all contained in a plastic box.

Placement of the transmission plate 14, receiving plates 18, and if present ground plate 24 are not particularly critical for correct operation of this device. For operation of the device without a ground plate 24, the transmission plate 14 should be centered on the side of the specimen to which it is adjacent. Likewise, the combination of the three receiving plates should, as a whole, be centered on the side of the specimen to which they are adjacent. Further, the transmission plate 14 and the receiving plates 18 are preferably on opposing sides of the specimen. For instance, if the specimen is a bale of cotton traveling down a conveyor, the best mode placement would be to place the transmission plate centered both in elevation with respect to the bale of cotton and centered with respect to length of the bale of cotton when the measurement is made. Further, the transmission plate 14 is preferably parallel to the side of the bale to which it is adjacent. Likewise, the receiving plates 18 are preferably centered with respect to elevation of the bale as well as the length of the bale, the plates are preferably parallel to the side of the bale to which it is adjacent, and further will be parallel to the transmission plate 14. It will be understood however that the invention is not limited to this exact placement with respect to the specimen being measured. Indeed the elevations of the transmission plate 14 and receiving plates 18 need not be the same nor does the placement with respect to the length of the specimen need be the same. It is an operable plate placement having the transmission plate 14 and receiving plates 18 on the same side of the specimen.

In configurations where a ground plate 24 is used, the ground plate 24 preferably lies in a plane which is preferably parallel to an adjacent face of the specimen to be measured. Further, the ground plate 24 is preferably centered between the transmission plate 14 and the receiving plates 18 and its plane is preferably at right angles to the planes of the receiving plates 18 and the transmission plate 14. It will be understood that the ground plate 24 need not be centered between the two plates and indeed the heights to the transmission plate 14 and receiving plates 16. It is contemplated that the usual installation of the device will be to measure the moisture content of a bale of cotton as that cotton rests upon a scale made mostly of metallic material. Indeed, such a scale would act as the ground plate 24. In this configuration, the transmission plate 14 and the receiving plates 18 would be centered with respect to the length of the bale.

As for the particular circuitry of the preferred embodiment, the specification has included many part numbers for the operational amplifiers, transistors, diodes and the like. Based on the frequency of use in a cotton gin, these devices represent the best mode known to the inventor at the time of filing this specification. For operation in this particular application, a voltage of approximately 400 volts peak was applied to the transmission plate 14. The waveform of the voltage applied to the transmission plate 14 oscillates around zero volts and therefore the highest positive voltage applied to the transmission plate 14 is 400 volts and the most negative voltage applied to the transmission plate 14 is −400 volts. However, the invention is not limited to applying a sinusoidal voltage with no offset to the transmission plate 14. Indeed, it maybe possible to add sufficient direct current bias to the applied voltage such that only a time varying positive voltage would be applied to the transmission plate 14. Likewise, a negative direct current bias could be added such that only negative voltages could be applied to the transmission plate 14 and all of such would still be within the contemplation of this device.

In the application of measuring the moisture content of a cotton bale, the preferred use is to leave electric field generator 6 portion of the device operational at all times. Further, as a bale of cotton moves down a conveyor, it is contemplated that the best mode is to stop the bale of cotton such that the transmission plate 14 and the receiving plates 18 are centered as previously described so that a measurement may be taken. However, it is within the contemplation of this device that the moisture content of the bale of cotton could be done as it moves down conveying means without stopping for the moisture measurement.

In the best mode operation of the device the transmission plate 14 and the receiving plates 18 should be at least 6 inches away from the specimen being measured, for instance a bale of cotton. At plate to specimen separations greater than 12 inches, the device may still be operational, but such will require modification to the electrical circuits. Further, the one mega-ohm variable resistance coupling one lead of each of the receiving plates to ground is preferably set to 0.5 mega-ohms. This setting may change however based on the specimen being measured, transmission and receiving plate separation from the specimen, and peak voltage applied to the transmission plate.

Operation of the device is relatively simple. In the application where the moisture content of a bale of cotton is determined, the electric field generator 6 is placed on one side of a path of travel of the cotton bale. This path of travel of a cotton bale is usually along a conveyor of some sort leading away from the cotton gin's baling equipment. On a second side in operation relationship to the electric field generator 6 will be placed the electric field detector 8. In this configuration, the conveying means will move the bale of cotton to be between the electric field generator 6 and the electric field detector 8. When the bale of cotton is in this position the electric field created by the electric field generator 6 will permeate the cotton bale 26 and the electric field detector 8 will measure the effect the moisture of the cotton bale 26 has on the electric field.

In the situation where the moisture measuring device is measuring a bale of cotton, the current state-of-the-art in making cotton bales is to hold the bale together with metallic bands. In some circumstances, after the bale is bound together with the metallic bands, a plastic cover is placed over the bale and bands. In applications where this is done, there is little chance that the metallic bands binding the cotton together may become grounded. However, it is contemplated that some applications of the device may be in situations where the metallic bands are exposed on the outer surface of the cotton bale and therefore there is at least the possibility that the bands themselves may become grounded as they move down a conveyor of metallic rollers. The possibility of a band becoming grounded is usually slight since the spacing of the rollers on a conveyor are different than the spacing of the bands on a bale which, in combination with the bunching effect created by the bands, make it unlikely that a band will drop far enough to contact a grounded metallic roller of a conveyor. Other conveying systems may be rubber belts which further lessen the possibility of grounding a metallic band. The bands themselves in their ungrounded state have little if any effect on the operation of the moisture measuring device. If by chance one of the bands becomes grounded, such grounded band will affect the moisture measuring capability of the device, but this effect is not substantial. Because of multiple plates, two or more bands have to ground at the same time to affect unit operation.

A second application of the moisture measuring characteristics of this device is shown in FIG. 8. In this figure, cotton 32 falls within a chute bounded by electrically conductive material 30. Disposed within the walls of the chute will be the transmission plate 14 and the receiving plate 18. So that electric fields may be generated and detected, the transmission plate 14 and receiving plate 18 must be electrically isolated from the conductive material 30 and such is done by presence of insulating material 28. Operation of the moisture measuring device in this configuration is very similar to the configuration without a ground plate and with a conveying means. In this case, the transmission plate 14 creates an electric field existing at least within the specimen space bounded by the conductive material 30. The receiving plate or plates 18 has a voltage induced upon it proportional to the electric field produced. As the moisture laden cotton 32 falls within the chute bounded by the conductive material 30, the moisture of the cotton 32 affects the electric field produced by the transmission plate 14. The electric field detector 8 then determines a moisture content of the cotton 32 as previously described and produces an output signal for use by other gin machinery.

This document does not intend to distinguish between components that differ in name, but not in function. In the proceeding discussion, the terms “including” and “comprising” are used in an open-ended fashion, and thus should be interpreted to mean “including, but not limited to . . . ”. Also, the term “couple” or “couples” is intended to mean either an indirect or direct electrical connection. Thus, if a first device couples to a second device, that connection may be through a direct electrical connection or an indirect electrical connection via other devices and connections.

It must be understood that the theory of operation of the device as previously described is based on the theory of electric fields, the theory of electric field lines, and the flow of electric flux. This is only a theory explaining the characteristics of an electric field and should not be construed as a limitation on operation of the device. It is possible to completely explain operation of this electric field device by means of the cumulative effect of the electric di-pole of water in the specimen being measured, yet the electronics, plate placement and tuning would remain exactly the same. Stated a different way, the device should not be construed to be limited in the creation of electric field lines through the specimen to be measured or the flow of electric flux from the transmission plate to a surrounding ground or ground plate. It is the same invention to say that an electric field is created on a transmission plate 14 which tends to align the electric di-poles of the water in the specimen and it is the alignment of the di-poles in a particular direction that creates an electric field emanating from the specimen on its far side because of this alignment.

By the above specifications and drawings, one with ordinary skill in the art will understand how to make and use the invention as described. At this time the description above includes the best mode known to the inventor of carrying out his invention.

The embodiment shown and described above is only exemplary. I do not claim to have invented all the parts, elements or steps described. Various modifications can be made in the construction, material, arrangement, and operation, and still be within the scope of this invention. For example, this specification has used the term conductive plate to be both the transmission plate 14 and receiving plates 18. It is within the contemplation of this invention that rather than using plates as the charged element to create the electric field or a conductive element to detect the electric field that instead a wire mesh could be used. Likewise, given the right circumstances even a single strand of wire could be used to create the electric field and such would still be within the contemplation of this invention. Indeed, any conductive element to which a charge could be applied to create an electric field could be substituted for the conductive plates.

The restrictive description and drawings of the specific examples above do not point out what an infringement of this patent would be, but are to enable one skilled in the art to make and use the invention. The limits of the invention and the bounds of the patent protection are measured by and defined in the following claims.

I claim as my invention:

1. A method of measuring a moisture content of a specimen comprising:
generating an electric field and substantially no related magnetic field, wherein the electric field has an intensity;
placing the specimen within the electric field; and
measuring an effect the moisture of the specimen has on the electric field intensity.

2. The method as defined in claim 1 wherein the measuring step further comprises:
detecting an increase in the electric field intensity directly proportional to the moisture content of the specimen.

3. The method of measuring moisture content as defined in claim 2 wherein generating and measuring the electric field further comprises:
applying a voltage to a first electrically conductive element to create the electric field;
placing a second electrically conductive element within the electric field; and
determining the moisture content based on the effect the moisture of the specimen has on the electric field intensity; by
detecting a change in a voltage induced on the second electrically conductive element proportional to the electric field intensity.

4. The method as defined in claim 1 wherein the measuring step further comprises:
placing a substantially zero potential electrically conductive element within the electric field; and
detecting a decrease in the electric field intensity inversely proportional to the moisture content of the specimen.

5. A method of measuring a moisture content of a specimen comprising:
a) generating substantially only an electric field having an intensity; by
i) creating a time varying voltage having a frequency;
ii) applying the time varying voltage to a first electrically conductive plate;
b) placing the specimen within the electric field;
c) measuring an effect the moisture of the specimen has on the electric field intensity; by
i) placing a second electrically conductive plate within the electric field;
ii) detecting an induced voltage on the second electrically conductive plate, wherein the induced voltage is responsive to the effect of the moisture of the specimen on the electric field; and
d) creating an output signal based on said induced voltage related to the moisture of the specimen.

6. The method as defined in claim 5 wherein the frequency of the time varying voltage is approximately 50,000 cycles per second.

7. The method of measuring the moisture content of cotton by using the steps of claim 5 with cotton as the specimen.

8. The method of measuring the moisture content of cotton by using the steps of claim 5 with seed cotton as the specimen.

9. The method of measuring the moisture content of cotton by using the steps of claim 6 with lint cotton as the specimen.

10. The method of measuring the moisture content of cotton by using the steps of claim 5 with lint cotton in a bale as the specimen.

11. The method as defined in claim 5 further comprising the output signal in a range of 4 to 20 milli-amp direct current.

12. The method of measuring the moisture content of a specimen as defined in claim 5 further comprising:
e) placing the first and second conductive plates on opposing sides of a path of travel of the specimen;
f) moving the specimen along the path of travel; and
g) measuring the moisture content of the specimen while said specimen is between said conductive plates.

13. The method as defined in claim 12 wherein said path of travel is substantially horizontal.

14. The method as defined in claim 12 wherein the path of travel is substantially vertical.

15. A moisture measuring device for measuring a moisture content of a specimen, the moisture measuring device comprising:
a transmission plate having a voltage, wherein the voltage on the transmission plate creates an electric field having an intensity;
a plurality of receiving plates within the electric field, wherein each of the plurality of receiving plates has a voltage induced upon it proportional to the intensity of the electric field; and
wherein moisture of the specimen has an effect on the electric field intensity, and wherein the voltage induced on the receiving plates is proportional to the electric field intensity and therefore the moisture of the specimen.

16. The moisture measuring device as defined in claim 15 wherein the voltage on the transmission plate is a direct current (DC) voltage.

17. The moisture measuring device as defined in claim 15 wherein the voltage on the transmission plate is an alternating current (AC) voltage having a frequency.

18. The moisture measuring device as defined in claim 17 wherein the frequency is 50,000 Hertz.

19. The moisture measuring device as defined in claim 17 wherein the voltage induced on the plurality of receiving plates is an AC voltage.

20. The moisture measuring device as defined in claim 15 wherein the plurality of receiving plates are substantially co-planer.

21. The moisture measuring device as defined in claim 20 wherein the substantially co-planer receiving plates are substantially parallel to the transmissions plate, and wherein a specimen space lies substantially between the transmission plate and the receiving plates.

22. The moisture measuring device as defined in claim 15 wherein the plurality of receiving plates and the transmission plate are substantially co-planar, and wherein the plane of the transmission plate and receiving plates defines a boundary of the specimen space.

23. The moisture measuring device as defined in claim 15 wherein the plurality of receiving plates further comprises three receiving plates.

24. The moisture measuring device as defined in claim 15 wherein the receiving plates are constructed of aluminum.

25. The moisture measuring device as defined in claim 15 wherein the receiving plates further comprise:
a length;
a height;
a thickness; and
wherein the length and height are substantially the same.

26. The receiving plates as defined in claim 25 wherein the length and height are substantially three inches.

27. The receiving plates as defined in claim 25 wherein the thickness is substantially 0.02 inches.

28. The moisture measuring device as defined in claim 25 wherein both the transmission plate and the receiving plates are made of aluminum.

29. A method of measuring the moisture content of specimen, the method comprising:
a) applying a time varying voltage to an electrically conductive plate which creates a time varying electric field around the plate, but substantially no related electromagnetic wave;
b) placing a specimen having a moisture content in the electric field;
c) detecting an effect the moisture of the specimen has on the electric field by;
i) placing a plurality of electrically conductive receiving plates in the electric field; and
ii) measuring an effect the moisture of the specimen has on the electric field.

30. The method as defined in claim 29 wherein applying the time varying voltage to the electrically conductive plate further comprises:
generating a periodic waveform having a frequency; and
coupling the periodic waveform to the electrically conductive plate.

31. The method as defined in claim 30 wherein generating a periodic waveform having a frequency further comprises generating a substantially sinusoidal waveform.

32. The method as defined in claim 29 wherein placing a specimen in the electric field further comprises moving a bale of moisture laden cotton along a conveyor into the electric field.

33. The method as defined in claim 29 wherein step c) further comprises:
placing three electrically conductive receiving plates in the electric field;
measuring the effect the moisture of the specimen has on the electric field with each of the three electrically conductive receiving plates; and
averaging the measurements made using each of the three electrically conductive receiving plates to obtain an overall measurement.

34. The method as defined in claim 33 wherein measuring the effect the moisture of the specimen has on the electric field further comprises measuring a voltage induced on each of the three electrically conductive plates which voltage is directly proportional to the moisture content of the specimen.

35. The method as defined in claim 33 wherein measuring the effect the moisture of the specimen has on the electric field further comprises:
placing a ground plate within the electric field, said ground plate substantially at ground potential; and
measuring a voltage induced on each of the three electrically conductive plates which is inversely proportional to the moisture content of the specimen.

36. A structure of a moisture measuring device, comprising:
a signal generator generating a time varying signal;
a voltage amplifier coupled to the time varying signal, wherein the voltage amplifier produces a voltage amplified time varying signal;
a metallic transmission plate coupled to the voltage amplified time varying signal, wherein the voltage amplified time varying signal produces a time varying electric field around the transmission plate, but substantially no related electromagnetic wave;
a plurality of metallic receiving plates placed in operational relationship to the transmission plate, wherein a space between the transmission plate and the receiving plates defines a specimen space, and wherein the time varying electric field penetrates the specimen space;
a specimen within the specimen space, wherein the specimen has a moisture content that affects an intensity of the time varying electric field at the receiving plates;
a plurality of detection circuits coupled one each to the metallic receiving plates, wherein each of the detection circuits is configured to detect a voltage induced on the receiving plate and produce an output signal, and wherein the voltage induced is proportional to the intensity of the electric field at the receiving plate; and
a summing circuit coupled to each of said detection circuits, said summing circuit configured to combine the output signal of the detection circuits to produce a signal proportional to the moisture content of the specimen.

37. The moisture measuring device as defined in claim 36 wherein the time varying signal is periodic and has a frequency of 50,000 cycles per second.

38. The moisture measuring device as defined in claim 36 wherein the time varying signal has a peak voltage of 400 volts.

39. The moisture measuring device as defined in claim 36 wherein the plurality of receiving plates further comprises three receiving plates.

40. The moisture measuring device as defined in claim 36 wherein each of the plurality of receiving plates further comprises two conducting leads arranged in a labyrinth pattern around a center pad, and wherein a first of the two conducting leads couples to the detection circuit, and a second of the two conducting leads couples to ground through a resistor.

41. The moisture measuring device as defined in claim 40 wherein the resistor comprises a one mega-ohm potentiometer.
